(19) United States
(12) Patent Application Publication
(10) Pub. No.: US 2025/0379123 A1
(43) Pub. Date: Dec. 11, 2025

(54) BONDING STRUCTURE AND RELATED FABRICATION FOR A MEMORY SYSTEM

(71) Applicant: Micron Technology, Inc., Boise, ID (US)

(72) Inventors: Pankaj Sharma, Boise, ID (US); Richard J. Hill, Boise, ID (US); Shyam Surthi, Boise, ID (US); Yoshiaki Fukuzumi, Yokohama (JP)

(21) Appl. No.: 19/216,313

(22) Filed: May 22, 2025

Related U.S. Application Data
(60) Provisional application No. 63/657,684, filed on Jun. 7, 2024.

(51) Int. Cl. H01L 23/48; H01L 21/768; H10B 41/40; H10B 43/40

(52) U.S. Cl. CPC H01L 23/481; H01L 21/76898; H10B 41/40; H10B 43/40

(57) ABSTRACT

Methods, systems, and devices for a bonding structure and related fabrication for a memory system are described. The method may include forming a first layer that includes a polysilicon material, forming, above the first layer, a second layer that includes an oxide material, and forming, above the second layer, a third layer that include the polysilicon material. Additionally, the method may include removing a first portion of the first layer, a first portion of the second layer, and a third portion of the third layer to form a first cavity. Additionally, the method may include forming the oxide material in the first cavity, forming a plurality of second cavities based on removing some of the oxide material formed in the first cavity, and forming a set of first pillars based on forming a metal material in two or more cavities of the set of second cavities.

### CROSS REFERENCE

The present Application for Patent claims priority to U.S. Patent Application No. 63/657,684 by Sharma et al., entitled “BONDING STRUCTURE AND RELATED FABRICATION FOR A MEMORY SYSTEM,” filed Jun. 7, 2024, which is assigned to the assignee hereof, and which is expressly incorporated by reference in its entirety herein.

### TECHNICAL FIELD

The following relates to one or more systems for memory, including a bonding structure and related fabrication for a memory system.

### BACKGROUND

Memory devices are widely used to store information in various electronic devices such as computers, user devices, wireless communication devices, cameras, digital displays, and the like. Information is stored by programming memory cells within a memory device to various states. For example, binary memory cells may be programmed to one of two supported states, often corresponding to a logic 1 or a logic 0. In some examples, a single memory cell may support more than two possible states, any one of which may be stored by the memory cell. To access information stored by a memory device, a component may read (e.g., sense, detect, retrieve, identify, determine, evaluate) the state of one or more memory cells within the memory device. To store information, a component may write (e.g., program, set, assign) one or more memory cells within the memory device to corresponding states.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), 3-dimensional cross-point memory (3D cross point), not-or (NOR) and not-and (NAND) memory devices, and others. Memory devices may be described in terms of volatile configurations or non-volatile configurations. Volatile memory cells (e.g., DRAM) may lose their programmed states over time unless they are periodically refreshed by an external power source. Non-volatile memory cells (e.g., NAND) may maintain their programmed states for extended periods of time even in the absence of an external power source.

### BRIEF DESCRIPTION OF THE DRAWINGS

FIG. 1 shows an example of a memory device that supports a bonding structure and related fabrication for a memory system in accordance with examples as disclosed herein.

FIGS. 2 through 16 show examples of a portion that supports a bonding structure and related fabrication for a memory system in accordance with examples as disclosed herein.

FIG. 17 shows a block diagram of a memory system that supports a bonding structure and related fabrication for a memory system in accordance with examples as disclosed herein.

FIGS. 18 and 19 show flowcharts illustrating a method or methods that support a bonding structure and related fabrication for a memory system in accordance with examples as disclosed herein.

### DETAILED DESCRIPTION

In some examples, a memory system may include a 3D structure. In order to manufacture the 3D structure, a manufacturing system may perform one or more operations. For example, the manufacturing system may deposit or etch different materials (e.g., silicon material, metal material, or polysilicon material) in some order to create different components of the memory system (e.g., a memory array and peripheral components of the memory array). In some examples, a series of consecutive operations performed by the manufacturing system may be known as a module. Using other methods, the manufacturing system may open up the memory array (e.g., create connections between the memory array and contact pads of the memory system) using both a first module (e.g., a 4V mask) and a second module (e.g., a 4U mask). However, performing both the first module and the second module may increase cost and manufacturing time of the memory system.

As described herein, the manufacturing system may create the 3D structure of the memory system using one or more less modules (e.g., one or more less lithography, masking, or other steps) when compared to other methods. In some examples, the manufacturing system may produce a memory system that includes a die divided into a memory array region and a periphery region. Further, the manufacturing system may produce the die such that the periphery region of the die includes a first set of layers and a second set of layers. In some examples, a distance between a first surface of the die and the first set of layers may be smaller than a distance between the first surface and the second set of layers.

Additionally, the manufacturing system may produce the die such that the die includes a first set of pillars. In some examples, the first set of pillars may extend through the first set of layers and the second set of layers in a direction perpendicular to the first surface in order to couple with a contact pad included in the first surface. Further, each pillar of the first set of pillars may include a first portion that extends through the first set of layers and a second portion that extends through the second set of layers. In some examples, a cross-sectional area of the first portion may be larger than a cross-sectional area of the second portion. Creating the die in such a way may allow the manufacturing system to build the 3D structure of the memory system using one less module (e.g., complete elimination of the 4V mask).

In addition to applicability in memory systems as described herein, techniques for a bonding structure and related fabrication for a memory system may be generally implemented to improve the sustainability of various electronic devices and systems. As the use of electronic devices has become even more widespread, the amount of energy used and harmful emissions associated with production of electronic devices and device operation has increased. Further, the amount of waste (e.g., electronic waste) associated with disposal of electronic devices may also pose environmental concerns. Implementing the techniques described herein may improve the impact related to electronic devices by reducing the time, energy, or materials used in production of electronic devices, which may result in lowered production emissions and reduced electronic waste, among other potential benefits.

Features of the disclosure are illustrated and described in the context of systems, devices, and circuits. Features of the disclosure are further illustrated and described in the context of portions and flowcharts.

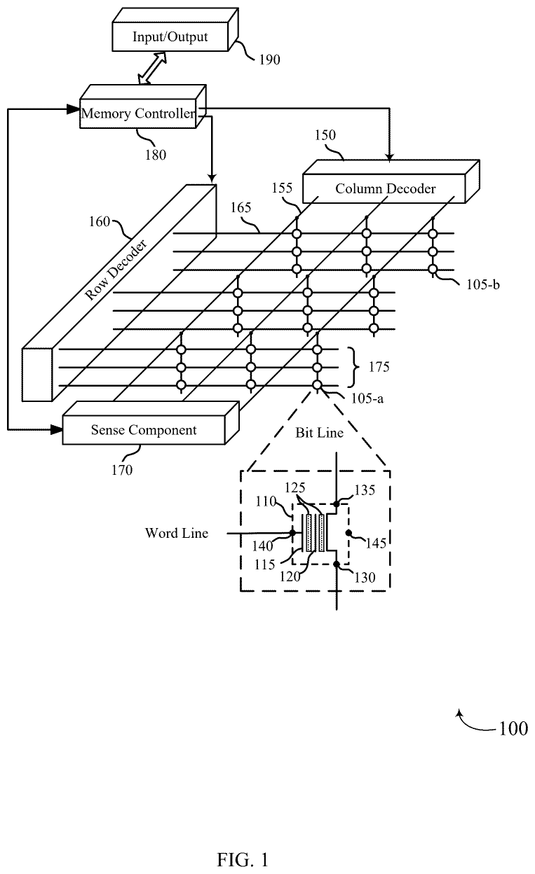

FIG. 1 shows an example of a memory device 100 that supports a bonding structure and related fabrication for a memory system in accordance with examples as disclosed herein. FIG. 1 is an illustrative representation of various components and features of the memory device 100. As such, the components and features of the memory device 100 are shown to illustrate functional interrelationships, and not necessarily physical positions within the memory device 100. Further, although some elements included in FIG. 1 are labeled with a numeric indicator, some other corresponding elements are not labeled, even though they are the same or would be understood to be similar, in an effort to increase visibility and clarity of the depicted features.

The memory device 100 may include one or more memory cells 105, such as memory cell 105-a and memory cell 105-b. In some examples, a memory cell 105 may be a NAND memory cell, such as in the blow-up diagram of memory cell 105-a. Each memory cell 105 may be programmed to store a logic value representing one or more bits of information. In some examples, a single memory cell 105—such as a memory cell 105 configured as a single-level cell (SLC)—may be programmed to one of two supported states and thus may store one bit of information at a time (e.g., a logic 0 or a logic 1). In some other examples, a single memory cell 105—such a memory cell 105 configured as a multi-level cell (MLC), a tri-level cell (TLC), a quad-level cell (QLC), or other type of multiple-level memory cell 105—may be programmed to one state of more than two supported states and thus may store more than one bit of information at a time. In some cases, a multiple-level memory cell 105 (e.g., an MLC memory cell, a TLC memory cell, a QLC memory cell) may be physically different than an SLC cell. For example, a multiple-level memory cell 105 may use a different cell geometry or may be fabricated using different materials. In some examples, a multiple-level memory cell 105 may be physically the same or similar to an SLC cell, and other circuitry in a memory block (e.g., a controller, sense amplifiers, drivers) may be configured to operate (e.g., read and program) the memory cell as an SLC cell, or as an MLC cell, or as a TLC cell, etc.

In some NAND memory arrays, each memory cell 105 may be illustrated as a transistor that includes a charge trapping structure (e.g., a floating gate, a replacement gate, a dielectric material) for storing an amount of charge representative of a logic value. For example, the blow-up in FIG. 1 illustrates a NAND memory cell 105-a that includes a transistor 110 (e.g., a metal-oxide-semiconductor (MOS) transistor) that may be used to store a logic value. The transistor 110 may include a control gate 115 and a charge trapping structure 120 (e.g., a floating gate, a replacement gate), where the charge trapping structure 120 may, in some examples, be between two portions of dielectric material 125. The transistor 110 also may include a first node 130 (e.g., a source or drain) and a second node 135 (e.g., a drain or source). A logic value may be stored in transistor 110 by storing (e.g., writing) a quantity of electrons (e.g., an amount of charge) on the charge trapping structure 120. An amount of charge to be stored on the charge trapping structure 120 may depend on the logic value to be stored. The charge stored on the charge trapping structure 120 may affect the threshold voltage of the transistor 110, thereby affecting the amount of current that flows through the transistor 110 when the transistor 110 is activated (e.g., when a voltage is applied to the control gate 115, when the memory cell 105-a is read). In some examples, the charge trapping structure 120 may be an example of a floating gate or a replacement gate that may be part of a 2D NAND structure. For example, a 2D NAND array may include multiple control gates 115 and charge trapping structures 120 arranged around a single channel (e.g., a horizontal channel, a vertical channel, a columnar channel, a pillar channel).

A logic value stored in the transistor 110 may be sensed (e.g., as part of a read operation) by applying a voltage to the control gate 115 (e.g., to control node 140, via a word line 165) to activate the transistor 110 and measuring (e.g., detecting, sensing) an amount of current that flows through the first node 130 or the second node 135 (e.g., via a bit line 155). For example, a sense component 170 may determine whether an SLC memory cell 105 stores a logic 0 or a logic 1 in a binary manner (e.g., based on a presence or absence of a current through the memory cell 105 when a read voltage is applied to the control gate 115, based on whether the current is above or below a threshold current). For a multiple-level memory cell 105, a sense component 170 may determine a logic value stored in the memory cell 105 based on various intermediate threshold levels of current when a read voltage is applied to the control gate 115, or by applying different read voltages to the control gate and evaluating different resulting levels of current through the transistor 110, or various combinations thereof. In one example of a multiple-level architecture, a sense component 170 may determine the logic value of a TLC memory cell 105 based on eight different levels of current, or ranges of current, that define the eight potential logic values that could be stored by the TLC memory cell 105.

An SLC memory cell 105 may be written by applying one of two voltages (e.g., a voltage above a threshold or a voltage below a threshold) to the memory cell 105 to store, or not store, an electric charge on the charge trapping structure 120 and thereby cause the memory cell 105 to store one of two possible logic values. For example, when a first voltage is applied to the control node 140 (e.g., via a word line 165) relative to a bulk node 145 (e.g., a body node) for the transistor 110 (e.g., when the control node 140 is at a higher voltage than the bulk), electrons may tunnel into the charge trapping structure 120. Injection of electrons into the charge trapping structure 120 may be referred to as programming the memory cell 105 and may occur as part of a write operation. A programmed memory cell may, in some cases, be considered as storing a logic 0. When a second voltage is applied to the control node 140 (e.g., via the word line 165) relative to the bulk node 145 for the transistor 110 (e.g., when the control node 140 is at a lower voltage than the bulk node 145), electrons may leave the charge trapping structure 120. Removal of electrons from the charge trapping structure 120 may be referred to as erasing the memory cell 105 and may occur as part of an erase operation. An erased memory cell may, in some cases, be considered as storing a logic 1. In some cases, memory cells 105 may be programmed at a page level of granularity due to memory cells 105 of a page sharing a common word line 165, and memory cells 105 may be erased at a block level of granularity due to memory cells 105 of a block sharing commonly biased bulk nodes 145.

In contrast to writing an SLC memory cell 105, writing a multiple-level (e.g., MLC, TLC, or QLC) memory cell 105 may involve applying different voltages to the memory cell 105 (e.g., to the control node 140 or bulk node 145 thereof) at a finer level of granularity to more finely control the amount of charge stored on the charge trapping structure 120, thereby enabling a larger set of logic values to be represented. Thus, multiple-level memory cells 105 may provide greater density of storage relative to SLC memory cells 105 but may, in some cases, involve narrower read or write margins or greater complexities for supporting circuitry.

A charge-trapping NAND memory cell 105 may operate similarly to a floating-gate NAND memory cell 105 but, instead of or in addition to storing a charge on a charge trapping structure 120, a charge-trapping NAND memory cell 105 may store a charge representing a logic state in a dielectric material between the control gate 115 and a channel (e.g., a channel between a first node 130 and a second node 135). Thus, a charge-trapping NAND memory cell 105 may include a charge trapping structure 120, or may implement charge trapping functionality in one or more portions of dielectric material 125, among other configurations.

In some examples, each page of memory cells 105 may be connected to a corresponding word line 165, and each column of memory cells 105 may be connected to a corresponding bit line 155 (e.g., digit line). Thus, one memory cell 105 may be located at the intersection of a word line 165 and a bit line 155. This intersection may be referred to as an address of a memory cell 105. In some cases, word lines 165 and bit lines 155 may be substantially perpendicular to one another, and may be generically referred to as access lines or select lines.

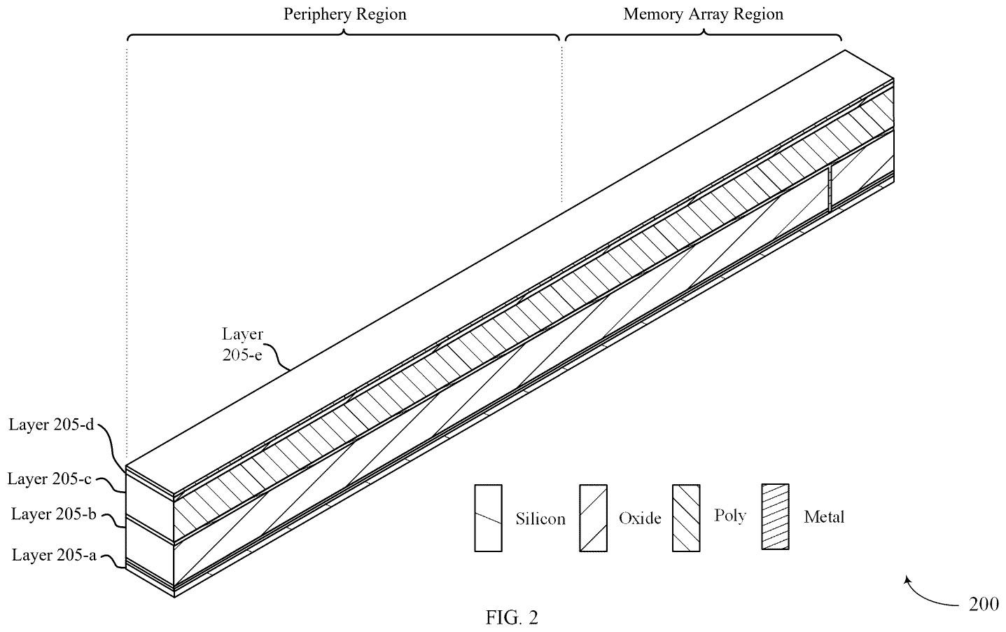

In some cases, a memory device 100 may include a three-dimensional (3D) memory array, where multiple two-dimensional (2D) memory arrays may be formed on top of one another. In some examples, such an arrangement may increase the quantity of memory cells 105 that may be fabricated on a single die or substrate as compared with 1D arrays, which, in turn, may reduce production costs, or increase the performance of the memory array, or both. In the example of FIG. 1, memory device 100 includes multiple levels (e.g., decks, layers, planes, tiers) of memory cells 105. The levels may, in some examples, be separated by an electrically insulating material. Each level may be aligned or positioned so that memory cells 105 may be aligned (e.g., exactly aligned, overlapping, or approximately aligned) with one another across each level, forming a memory cell stack 175. In some cases, memory cells aligned along a memory cell stack 175 may be referred to as a string of memory cells 105 (e.g., as described with reference to FIG. 2).

Accessing memory cells 105 may be controlled through a row decoder 160 and a column decoder 150. For example, the row decoder 160 may receive a row address from the memory controller 180 and activate an appropriate word line 165 based on the received row address. Similarly, the column decoder 150 may receive a column address from the memory controller 180 and activate an appropriate bit line 155. Thus, by activating one word line 165 and one bit line 155, one memory cell 105 may be accessed. As part of such accessing, a memory cell 105 may be read (e.g., sensed) by sense component 170. For example, the sense component 170 may be configured to determine the stored logic value of a memory cell 105 based on a signal generated by accessing the memory cell 105. The signal may include a current, a voltage, or both a current and a voltage on the bit line 155 for the memory cell 105 and may depend on the logic value stored by the memory cell 105. The sense component 170 may include various circuitry (e.g., transistors, amplifiers) configured to detect and amplify a signal (e.g., a current or voltage) on a bit line 155. The logic value of memory cell 105 as detected by the sense component 170 may be output via input/output component 190. In some cases, a sense component 170 may be a part of a column decoder 150 or a row decoder 160, or a sense component 170 may otherwise be connected to or in electronic communication with a column decoder 150 or a row decoder 160.

A memory cell 105 may be programmed or written by activating the relevant word line 165 and bit line 155 to enable a logic value (e.g., representing one or more bits of information) to be stored in the memory cell 105. A column decoder 150 or a row decoder 160 may accept data (e.g., from the input/output component 190) to be written to the memory cells 105. In the case of NAND memory, a memory cell 105 may be written by storing electrons in a charge trapping structure or an insulating layer.

A memory controller 180 may control the operation (e.g., read, write, re-write, refresh) of memory cells 105 through the various components (e.g., row decoder 160, column decoder 150, sense component 170). In some cases, one or more of a row decoder 160, a column decoder 150, and a sense component 170 may be co-located with a memory controller 180. A memory controller 180 may generate row and column address signals in order to activate a desired word line 165 and bit line 155. In some examples, a memory controller 180 may generate and control various voltages or currents used during the operation of memory device 100.

As described herein, a manufacturing system may create a 3D structure of the memory device 100 using one or more less modules when compared to other methods. In some examples, the manufacturing system may produce a memory device 100 (or die) that is divided into a memory array region and a periphery region. Further, the manufacturing system may produce the memory device 100 such that the periphery region of the memory device 100 includes a first set of layers and a second set of layers. In some examples, a distance between a first surface of the die and the first set of layers may be smaller than a distance between the first surface and the second set of layers.

Additionally, the manufacturing system may produce the memory device 100 such that the memory device 100 includes a first set of pillars. In some examples, the first set of pillars may extend through the first set of layers and the second set of layers in a direction perpendicular to the first surface in order to couple with a contact pad included in the first surface. A contact pad, for example, may be able to be coupled (e.g., bonded) with a bonding wire, which in turn may be coupled with another die (e.g., via another contact pad on the other die) or an external pin of a package that includes the memory device 100. Further, each pillar of the first set of pillars may include a first portion that extends through the first set of layers and a second portion that extends through the second set of layers. In some examples, a cross-sectional area of the first portion may be larger than a cross-sectional area of the second portion. Creating the memory device 100 in such a way may allow the manufacturing system to build the 3D structure of the memory device 100 using one less module (e.g., complete elimination of the 4V mask).

FIGS. 2 through 16 illustrate examples of operations that support a bonding structure and related fabrication for a memory device in accordance with example as disclosed herein. Specifically, FIGS. 2 through 16 illustrate a sequence of operations for fabricating a material arrangement, which may be at least a portion of the memory device (e.g., a memory device 100). Although the material arrangement illustrates examples of certain relative dimensions and quantities of various features, aspects of the material arrangement may be implemented with other relative dimensions or quantities of such features in accordance with examples as disclosed herein. Further, FIGS. 2 through 16 illustrate a 3D sectional view of the material arrangement. The 3D sectional view shows one or more internal or external features of the material arrangement during the sequence of operations.

Operations illustrated in and described with reference to FIGS. 2 through 16 may be performed by a manufacturing system, such as a semiconductor fabrication system configured to perform additive operations such as deposition or bonding, subtractive operations such as etching, trenching, planarizing, or polishing, and supporting operations such as masking, patterning, photolithography, or aligning, among other operations that support the described techniques. In some examples, operations performed by such a manufacturing system may be supported by a process controller or its components as described herein.

FIG. 2 shows an example of a portion 200 of the material arrangement after a first set of operations. In some examples, the first set of operations may include forming a layer 205-a. In some examples, forming the layer 205-a may include depositing a layer of silicon material to form what may be known as a silicon substrate. Additionally or alternatively, the first set of operations may include forming a layer 205-b above the layer 205-a. Forming the layer 205-b may include depositing a layer of oxide material (e.g., tetraethyl orthosilicate (TEOS)) above the layer 205-a.

Additionally or alternatively, the first set of operations may include forming a layer 205-c above the layer 205-b. Forming the layer 205-c may include depositing a layer of polysilicon material such that a vertical height of the layer 205-c is equal to a first height (e.g., 300 nm). In some examples, one or more layers may be formed between the layer 205-b and the layer 205-c. For example, a layer of metal material may be deposited between the layer 205-b and the layer 205-c. Further, as shown in FIG. 2, the metal material may vertically extend from the layer of metal material into the layer 205-b and connect with the layer 205-a. In some examples, charge may build up in the silicon substrate and the metal material may allow the silicon substrate to discharge the built up charge.

Additionally or alternatively, the first set of operations may include forming a layer 205-d above the layer 205-c. Forming the layer 205-d may include depositing a layer of oxide material such that a vertical height of the layer 205-d is equal to a second height (e.g., 20 nm). Additionally or alternatively, the first set of operations may include forming the layer 205-e above the layer 205-d. Forming the layer 205-e may include depositing a layer of polysilicon material such that a vertical height of the layer 205-e is equal to a third height (e.g., 20 nm). In some examples, the layer 205-e may be known as cap polysilicon.

As shown in FIG. 2, the portion 200 may include multiple regions. For example, the portion 200 may include a memory array portion and a periphery region. The memory array portion may be allocated for a memory array of the material arrangement and the periphery region may be allocated for periphery components associated with the memory array (e.g., access line drivers or sense components).

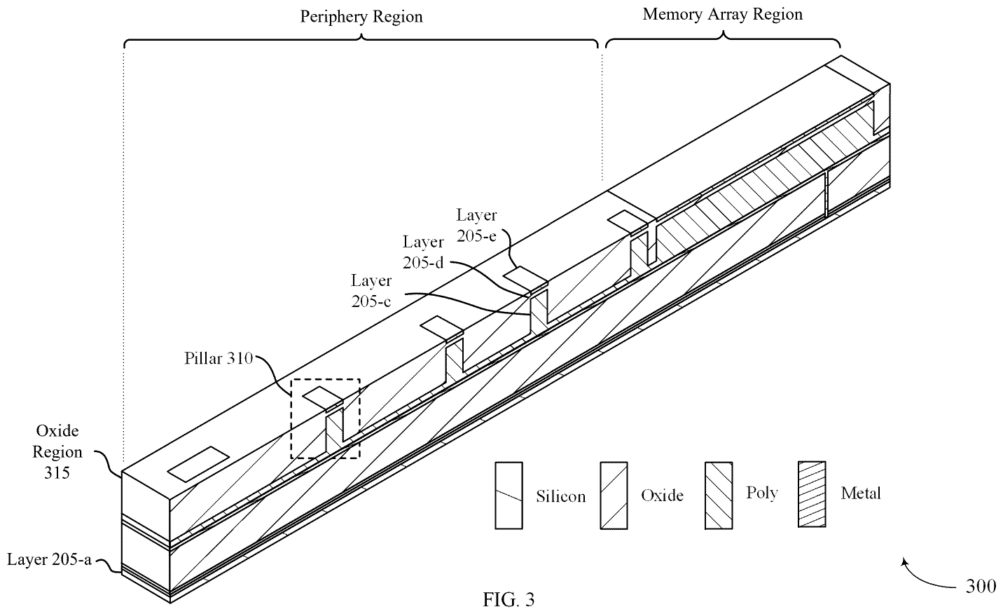

FIG. 3 shows an example of a portion 300 of the material arrangement after a second set of operations. In some examples, the second set of operations may include removing a respective portion of one or more of the layers 205 in the periphery region. For example, the second set of operations may include removing a first portion of the layer 205-e, a first portion of the layer 205-d, and a first portion of the layer 205-c in the periphery region. Specifically, the second set of operations may include etching 20 nm of the layer 205-e, 20 nm of the layer 205-d, and 250 nm of the layer 205-c according to some pattern.

In some examples, removing the respective portions of the one or more layers 205 may form a first cavity and one or more pillars 310 (e.g., three pillars 310) in the periphery region. Each of the one or more pillars 310 may include a respective second portion of the layer 205-e, a respective second portion of the layer 205-d, and a respective second portion of the layer 205-c that remains after removing the first portion of the layer 205-e, the first portion of the layer 205-d, and the first portion of the layer 205-c from the periphery region. That is, each pillar 310 may include the oxide material and the polysilicon material.

Additionally or alternatively, the second set of operations may include forming (or depositing) the oxide material in the first cavity. In some examples, the oxide material formed in the first cavity may be known as an oxide region 315. In some examples, the oxide region 315 may be formed such that the oxide material covers the top surface of the layer 205-e of the pillars 310 (not shown in FIG. 3). In other words, a vertical distance between the layer 205-a and a top surface of the oxide region 315 may be greater than a vertical distance between the layer 205-a and a top surface of the layer 205-e. In some examples, the oxide region 315 may be known as the Ruby Liner.

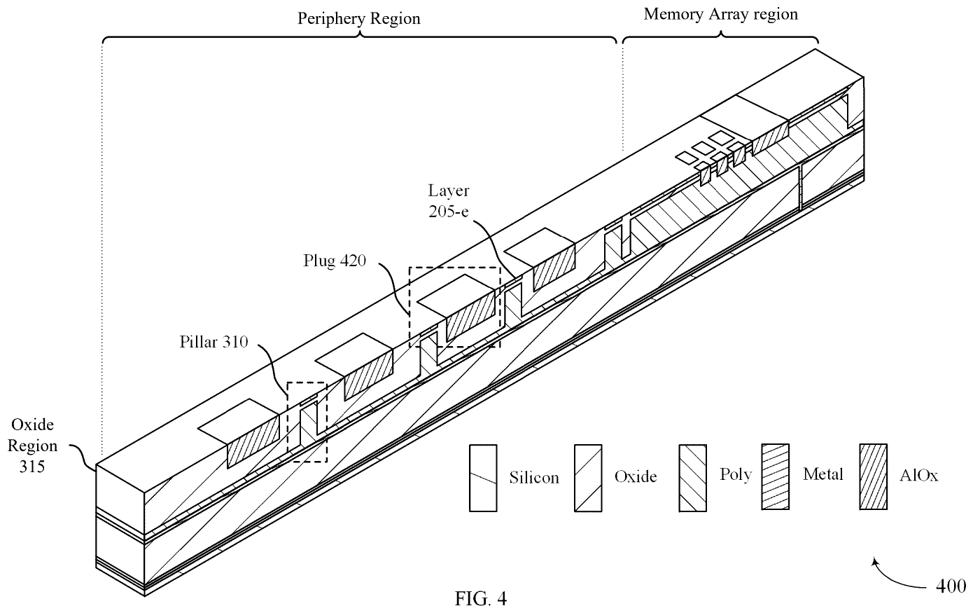

FIG. 4 shows an example of a portion 400 of the material arrangement after a third set of operations. In some examples, the third set of operations may include removing some of the oxide region 315 to form a set of second cavities (e.g., four cavities). Additionally or alternatively, the third set of operations may include forming (or depositing) aluminum oxide material in the cavities to form plugs 420. Additionally or alternatively, the third set of operations may include removing (e.g., via chemical-mechanical polishing (CMP)) some of the aluminum oxide material of the plugs 420 such that top surfaces of the plugs 420 may be flush (or level) with a top surface of the oxide region 315 or a top surface of the layer 205-e of the pillars 310. Further, in some examples, at least one plug 420 may be positioned between two respective pillars 310.

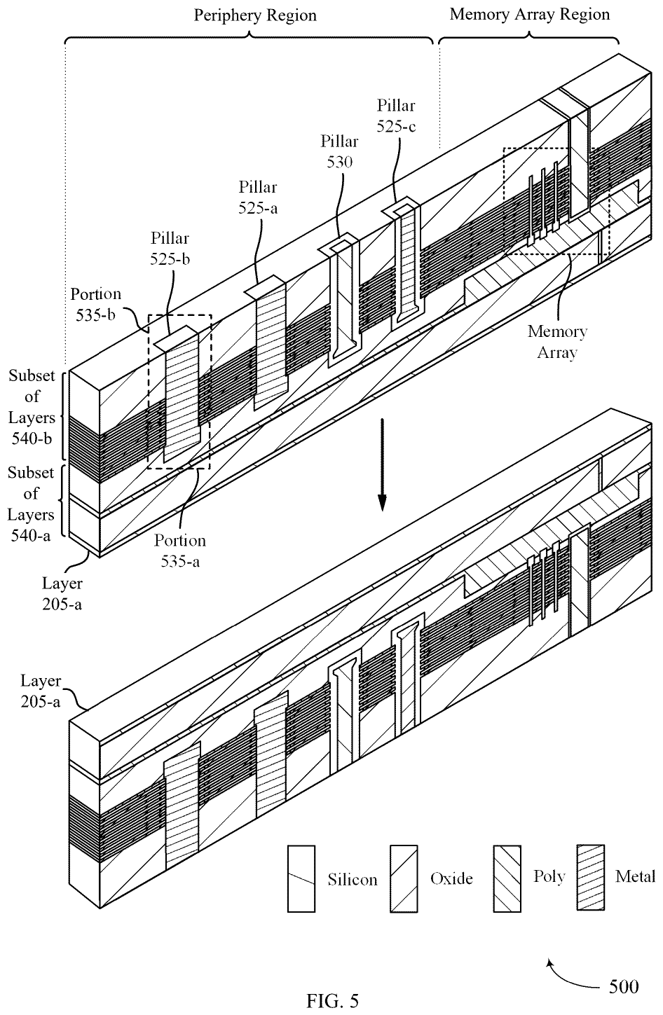

FIG. 5 shows an example of a portion 500 of the material arrangement after a fourth set of operations. In some examples, the fourth set of operations may include forming a set of pillars 525 (e.g., a pillar 525-a, a pillar 525-b, and a pillar 525-c) and a set of pillars 530 (e.g., the pillar 530) in the periphery region of the portion 500. The set of pillars 525 (e.g., live pillars or rivet pillars) may include the metal material and the set of pillars 530 (e.g., dummy pillar) may include the silicon material.

Further, each pillar 525 of the set of pillars 525 and each pillar 530 of the set of pillars 530 may include at least a respective portion 535-a and a respective portion 535-b. In some examples, the respective portion 535-a may extend through at least one layer of a subset of layers 540-a of the portion 500 and the respective portion 535-b may extend through at least one layer of a subset of layers 540-b of the portion 500.

In some examples, each of the subset of layers 540 may include one or more consecutive layers included in a stack of layers that make up the material arrangement. The subset of layers 540-a may be positioned differently in the stack of layers when compared to the subset of layers 540-b. For example, a vertical distance between the subset of layers 540-a and a first surface (e.g., a top surface or a bottom surface) of the material arrangement may be smaller than a vertical distance between the second subset of layers 540-b and the first surface of the material arrangement.

To form the respective portions 535-a of the pillars 525, the fourth set of operations may include removing the aluminum oxide material (or the plugs 420) from some of the second cavities (e.g., three of the second cavities) and forming the metal material in the second cavities. To form the respective portions 535-a of the pillars 530, the fourth set of operations may include removing the aluminum oxide material (or plugs) from some of the second cavities (e.g., one of the second cavities) and forming silicon material in the second cavities. In some examples, a portion 535-a may be of a different size than the portion 535-b. For example, a cross sectional area (e.g., a horizontal cross-sectional area) of the portion 535-a may be larger than a cross sectional area (e.g., a horizontal cross-sectional area) of the portion 535-b. In such example and as shown in FIG. 5, the pillars 525 and the pillars 530 may exhibit a t-shape.

Additionally or alternatively, the fourth set of operation may include forming a memory array in the memory array region of the portion 500. Additionally or alternatively, the fourth set of operations may include flipping the portion 500 such that the layer 205-a is the topmost layer of the portion 500 as opposed to the bottommost layer.

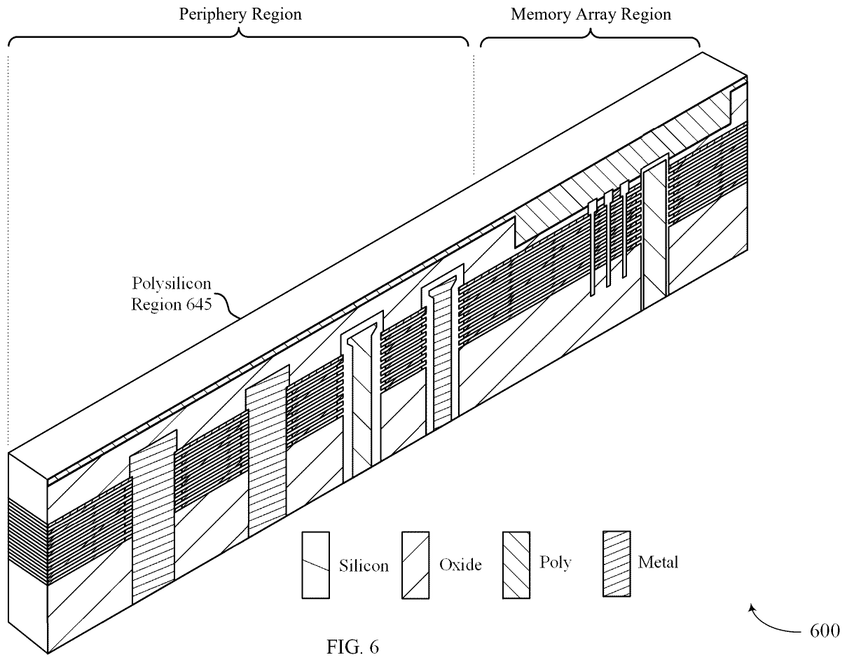

FIG. 6 shows an example of a portion 600 of the material arrangement after a fifth set of operations. In some examples, the fifth set of operations may including removing one or more of the layers 205. For example, the fifth set of operations may include removing at least the layer 205-a (e.g., via silicon wet removal) and the layer 205-b (e.g., via CMP). In some examples, removing the layer 205-a and the layer 205-b may expose a top surface of a polysilicon region 645. In some examples, the polysilicon region 645 may include any remaining polysilicon material of the layer 205-b after the second set of operations as described in FIG. 3.

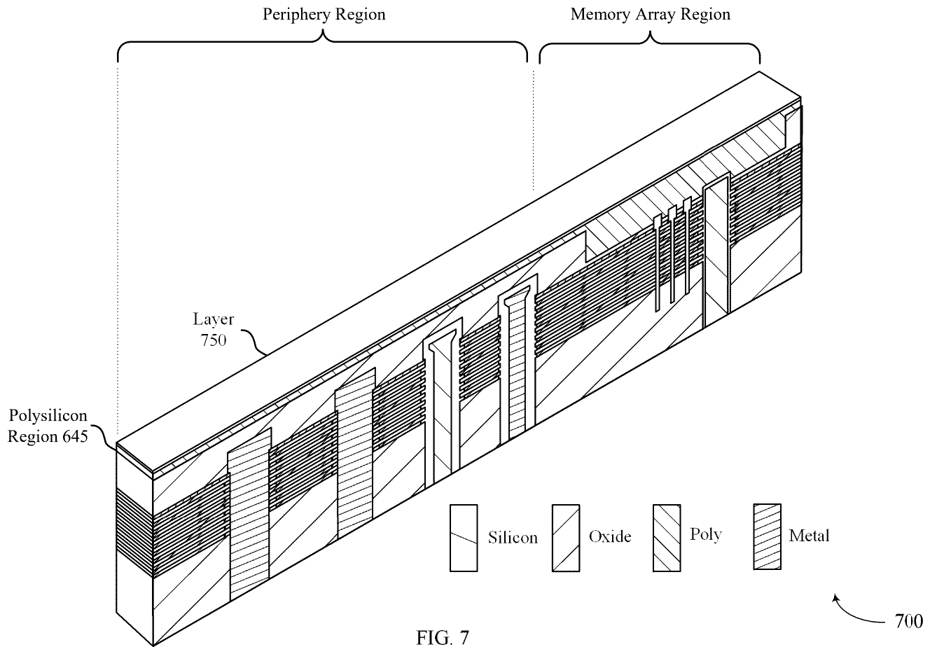

FIG. 7 shows an example of a portion 700 of the material arrangement after a sixth set of operations. In some examples, the sixth set of operations may include forming a layer 750 above the polysilicon region 645. Forming the layer 750 may include depositing a layer of the oxide material such that a vertical height of the layer 205-d is equal to a fourth height (e.g., 35 nm).

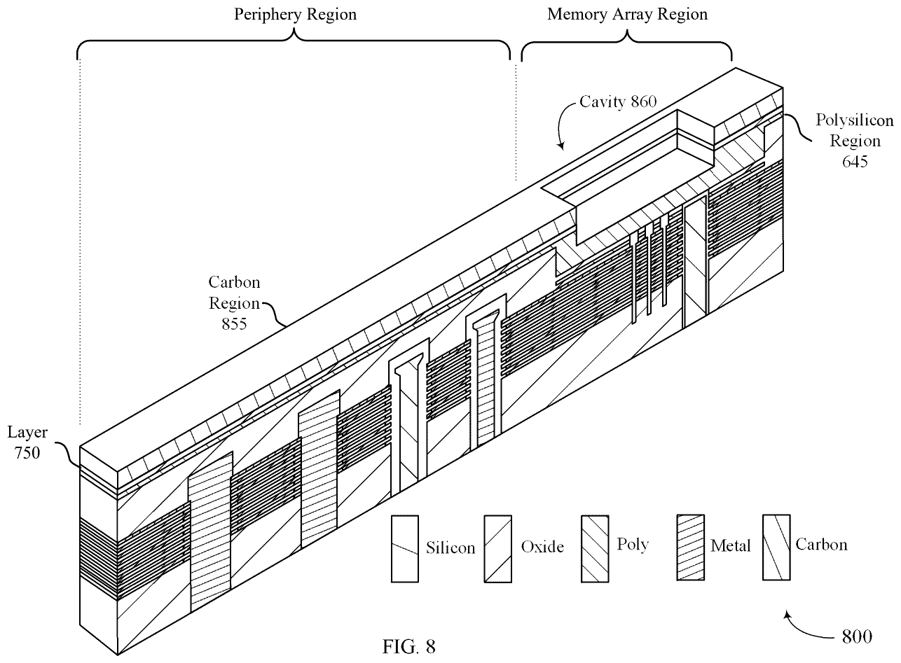

FIG. 8 shows an example of a portion 800 of the material arrangement after a seventh set of operations. In some examples, the seventh set of operations may including forming a carbon layer above the layer 750 by depositing carbon material. Additionally or alternatively, the seventh set of operation may include removing some of the carbon material from the carbon layer, removing some of the oxide material from the layer 750, and removing a first portion of the polysilicon material from the polysilicon region 645 to a form a cavity 860 in the memory array region of the portion 800. In some examples, a carbon region 855 may include the remaining carbon material of the carbon layer after removal of the carbon material from the carbon layer.

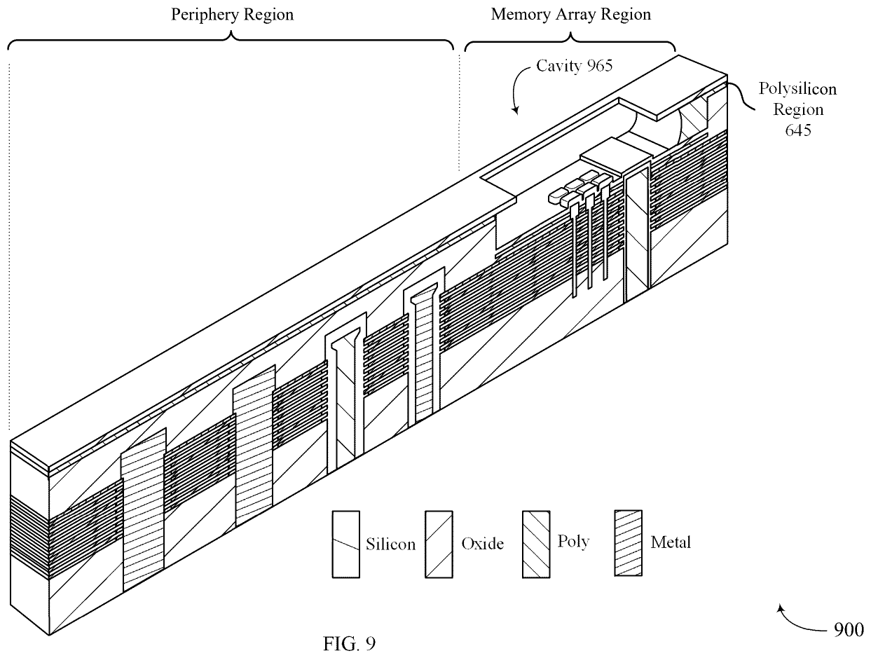

FIG. 9 shows an example of a portion 900 of the material arrangement after an eighth set of operations. In some examples, the eighth set of operations may include removing the carbon region 855. Alternatively or additionally, the eighth set of operations may include removing (e.g., via wet removal) a second portion of the polysilicon region 645 in the cavity 860 to form the cavity 965. In some examples, removing the second portion of the polysilicon region 645 may create an overhang of oxide material in the cavity 965.

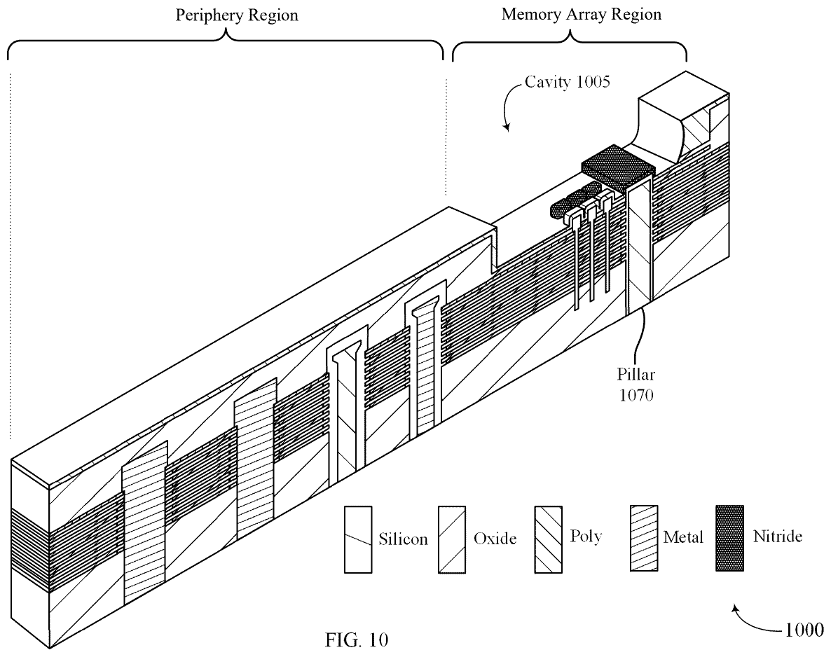

FIG. 10 shows an example of a portion 1000 of the material arrangement after a ninth set of operations. As shown in FIG. 10, the memory array region of the portion 1000 may include one or more memory array components that extend (e.g., vertically) into the cavity 965 (e.g., a pillar 1070). In some examples, the ninth set of operation may include forming a protection barrier above the oxide material that covers the one or more memory array components. In some examples, forming the protection barrier may include depositing (e.g., via atomic layer deposition (ALD)) nitride material above the oxide material that covers the one or more memory array components. Additionally or alternatively, the ninth set of operations may include removing the remaining oxide material of the layer 750 and the exposed oxide material in the cavity 965 forming a cavity 1005.

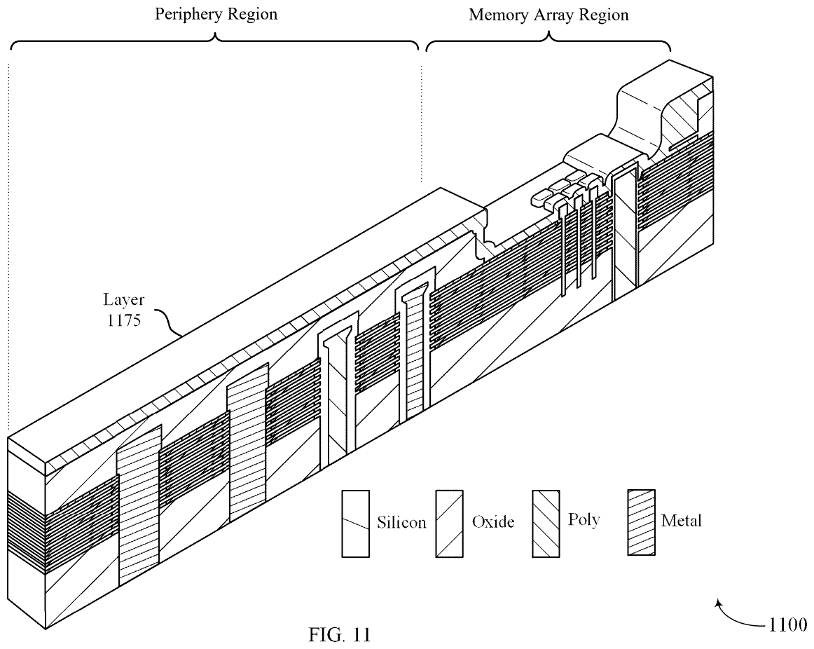

FIG. 11 shows an example of a portion 1100 of the material arrangement after a tenth set of operations. In some examples, the tenth set of operations may include removing the nitride material. Additionally or alternatively, the tenth set of operation may include forming a layer 1175. In some examples, forming the layer 1175 may include depositing the polysilicon material.

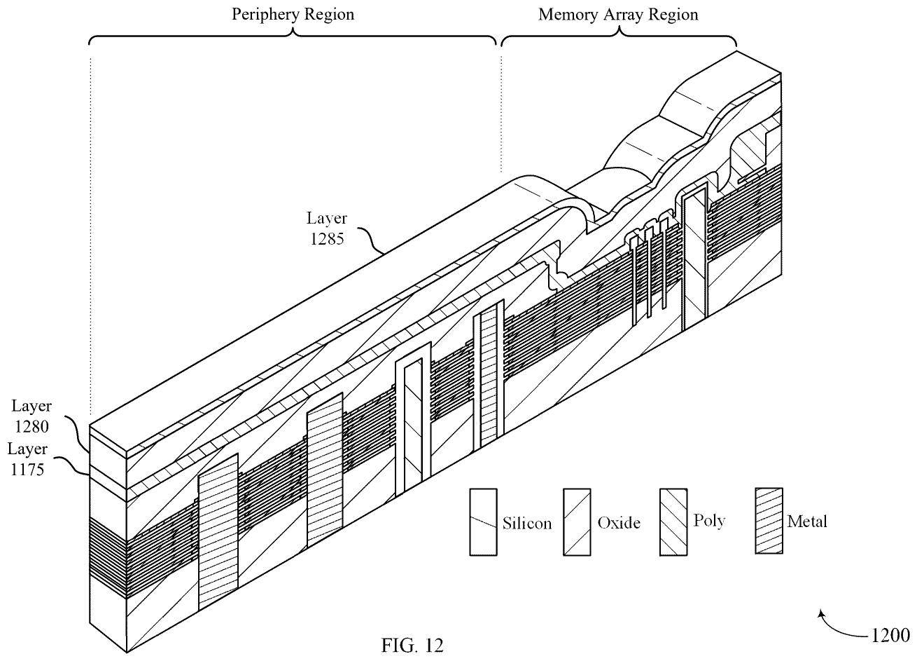

FIG. 12 shows an example of a portion 1200 of the material arrangement after an eleventh set of operations. In some examples, the eleventh set of operations may include forming a layer 1280 above the layer 1175. In some examples, forming the layer 1280 may include depositing oxide material. Additionally or alternatively, the eleventh set of operations may include forming a layer 1285 above the layer 1280. In some examples, forming the layer 1285 may include depositing the polysilicon material.

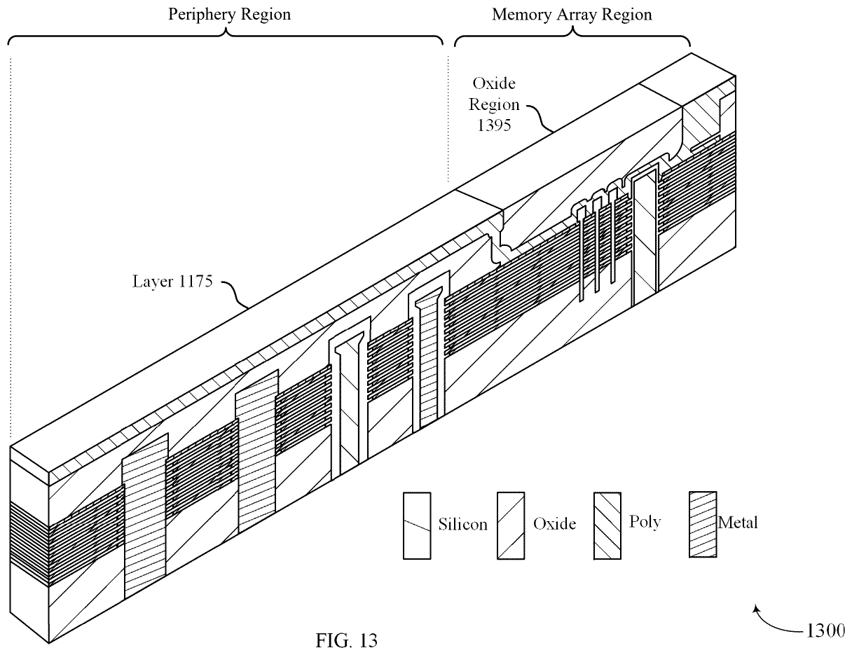

FIG. 13 shows an example of a portion 1300 of the material arrangement after a twelfth set of operations. In some examples, the twelfth set of operations may include removing (or etching) the layer 1285. Additionally or alternatively, the twelfth set of operations may include removing (or etching) a first portion of the layer 1285. As shown in FIG. 13, the first portion of the layer 1285 may be removed such that the remaining portion of the layer 1285 (e.g., oxide region 1395) is flush with (or at a same level as) the layer 1175.

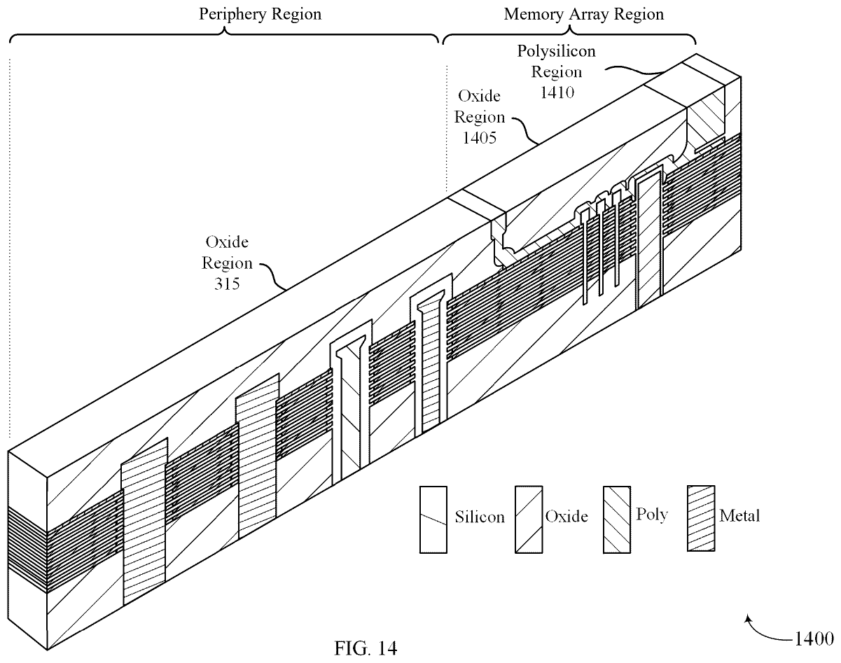

FIG. 14 shows an example of a portion 1400 of the material arrangement after a thirteenth set of operations. In some examples, the thirteenth set of operations may include removing (or etching) a first portion of the layer 1175. In some examples, a remaining portion of the layer 1175 may be known as a polysilicon region 1410. Additionally or alternatively, the thirteenth set of operations may include removing (or etching) a first portion of the oxide region 1395. In some examples, the remaining portion of the oxide region 1395 may be known as the oxide region 1405. As shown in FIG. 14, an exposed top surface of the oxide region 315, an exposed top surface of the oxide region 1405, and an exposed top surface of the polysilicon region may be flush with one another.

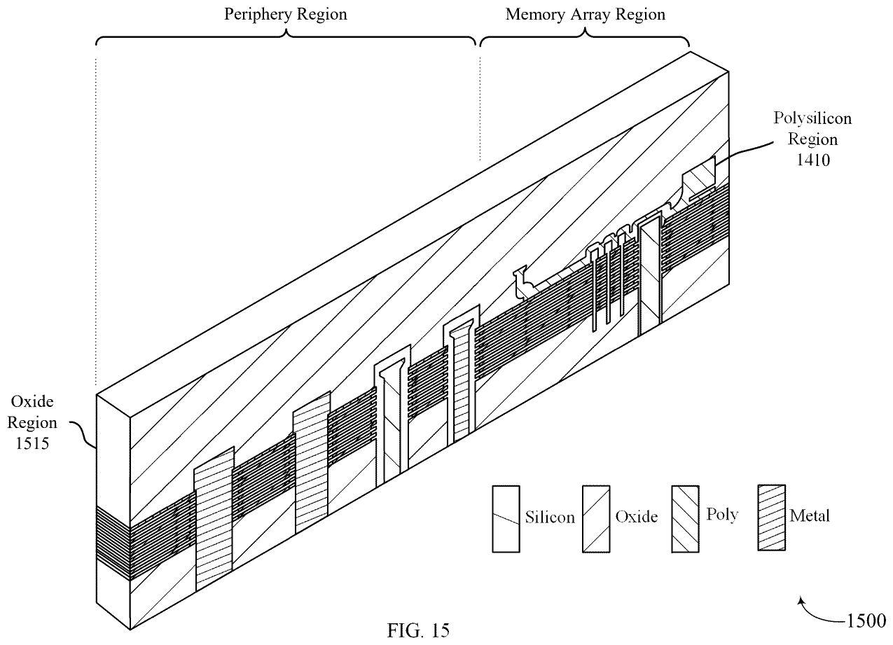

FIG. 15 shows an example of a portion 1500 of the material arrangement after a fourteenth set of operations. In some examples, the fourteenth set of operations may include forming an oxide region 1515. In some examples, forming the oxide region 1515 may include depositing oxide material above the oxide region 315, the oxide region 1405, and the polysilicon region 1410.

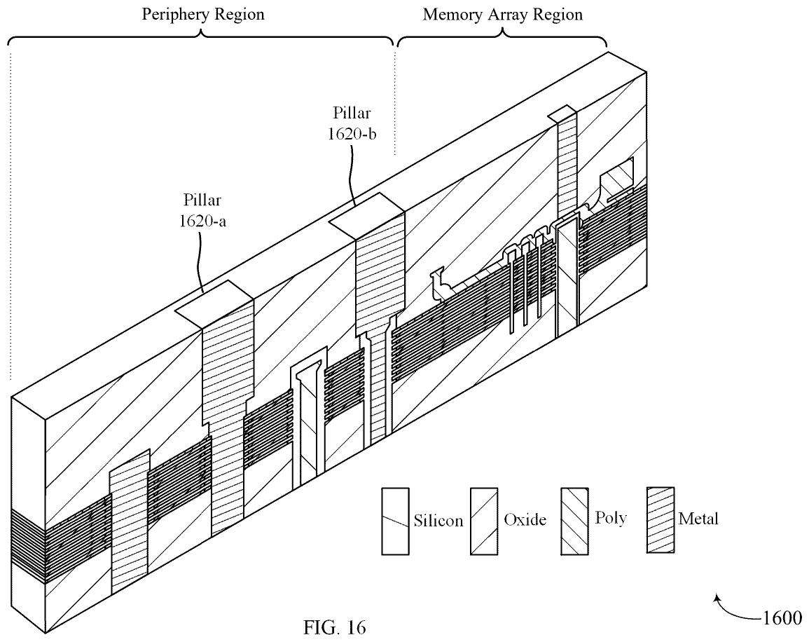

FIG. 16 shows an example of a portion 1600 of the material arrangement after a fifteenth set of operations. In some examples, the fifteenth set of operations may include forming one or more pillars 1620 (e.g., a pillar 1620-a and a pillar 1620-b). In some examples, forming the pillars 1620 may include removing respective portions of the oxide region 1515 to form respective cavities and forming metal material in the respective cavities. In some examples, the respective cavities may extend through the oxide region 1515 and connect with a portion of the pillars 525 (e.g., the portion 535-a). In some examples, each pillar 1620 may couple with a conductive pad (e.g., contact pad) included in a surface (e.g., a top surface or a bottom surface) of the material arrangement.

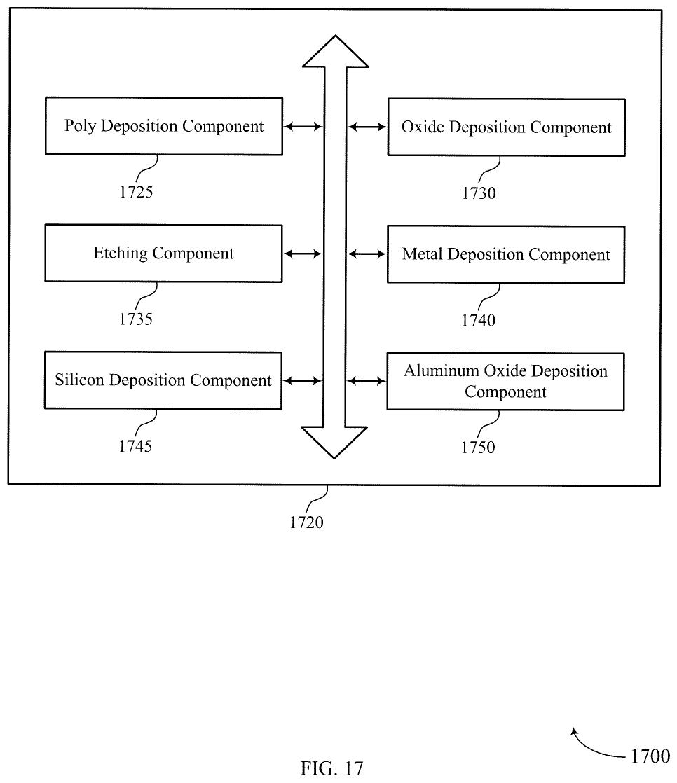

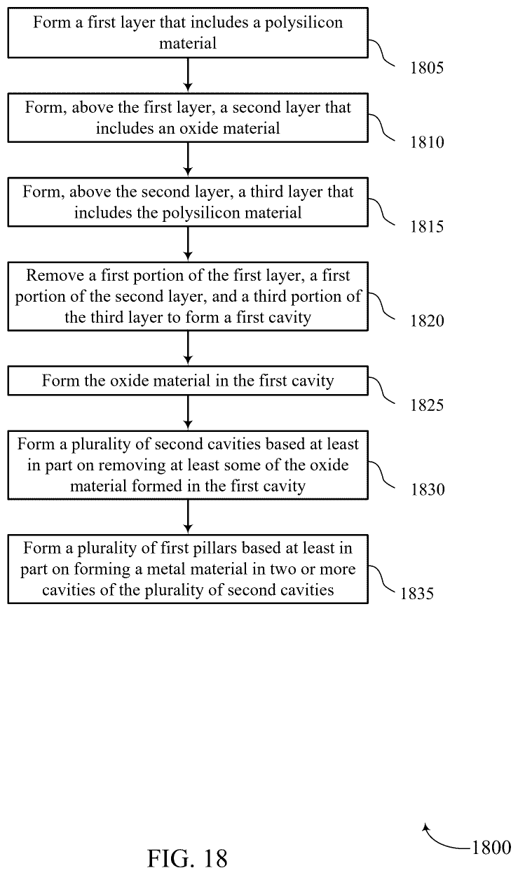

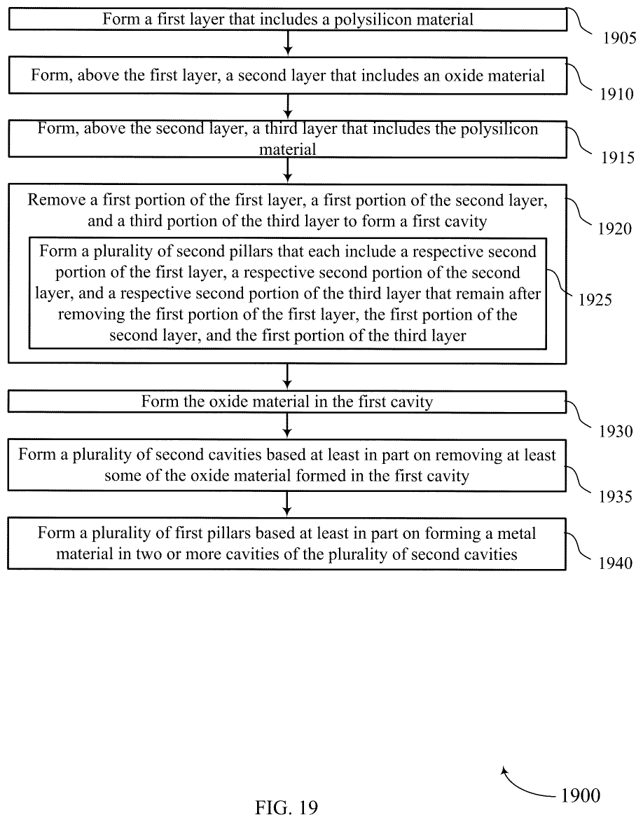

FIG. 17 shows a block diagram 1700 of a manufacturing system 1720 that supports a bonding structure and related fabrication for a memory system in accordance with examples as disclosed herein. The manufacturing system 1720 may be operable to perform operations as described with reference to FIGS. 2 through 16 as well as FIGS. 18 and 19.

The manufacturing system 1720, or various components thereof, may be an example of means for performing various aspects of a bonding structure and related fabrication for a memory system as described herein. For example, the manufacturing system 1720 may include a poly deposition component 1725, an oxide deposition component 1730, an etching component 1735, a metal deposition component 1740, a silicon deposition component 1745, an aluminum oxide deposition component 1750, or any combination thereof. Each of these components, or components of subcomponents thereof (e.g., one or more processors, one or more memories), may communicate, directly or indirectly, with one another (e.g., via one or more buses).

The poly deposition component 1725 may be configured as or otherwise support a means for forming a first layer that includes a polysilicon material. The oxide deposition component 1730 may be configured as or otherwise support a means for forming, above the first layer, a second layer that includes an oxide material. In some examples, the poly deposition component 1725 may be configured as or otherwise support a means for forming, above the second layer, a third layer that includes the polysilicon material. The etching component 1735 may be configured as or otherwise support a means for removing a first portion of the first layer, a first portion of the second layer, and a third portion of the third layer to form a first cavity. In some examples, the oxide deposition component 1730 may be configured as or otherwise support a means for forming the oxide material in the first cavity. In some examples, the etching component 1735 may be configured as or otherwise support a means for forming a plurality of second cavities based at least in part on removing at least some of the oxide material formed in the first cavity. The metal deposition component 1740 may be configured as or otherwise support a means for forming a plurality of first pillars based at least in part on forming a metal material in two or more cavities of the plurality of second cavities.

In some examples, to support removing the first portion of the first layer, the first portion of the second layer, and the first portion of the third layer, the etching component 1735 may be configured as or otherwise support a means for forming a plurality of second pillars that each include a respective second portion of the first layer, a respective second portion of the second layer, and a respective second portion of the third layer that remain after removing the first portion of the first layer, the first portion of the second layer, and the first portion of the third layer.

In some examples, one or more first pillars within the plurality of first pillars are each positioned between a respective set of at least two second pillars of the plurality of second pillars. In some examples, the silicon deposition component 1745 may be configured as or otherwise support a means for forming silicon material in a second cavity of the plurality of second cavities to form a third pillar.

In some examples, the silicon deposition component 1745 may be configured as or otherwise support a means for forming, prior to forming the first layer, a fourth layer that includes silicon material and is below the first layer. In some examples, a first distance between the fourth layer and a top surface of the third layer is less than a second distance between the first layer and a top surface of the oxide material formed in the first cavity.

In some examples, the aluminum oxide deposition component 1750 may be configured as or otherwise support a means for forming, prior to forming the metal material in the plurality of first pillars, aluminum oxide material in the plurality of second cavities to form a plurality of fourth pillars. In some examples, a top surface of the aluminum oxide material is flush with the top surface of the third layer or the top surface of the oxide material formed in the first cavity.

In some examples, the metal deposition component 1740 may be configured as or otherwise support a means for forming, prior to forming the first layer, a fifth layer that includes the metal material and is below the first layer. In some examples, the oxide deposition component 1730 may be configured as or otherwise support a means for forming, prior to forming the first layer, a sixth layer that includes the oxide material and is below the first layer.

In some examples, a first depth associated with the first layer is greater than a second depth associated with the second layer. In some examples, a first depth associated with the first layer is greater than a third depth associated with the third layer.

In some examples, the described functionality of the manufacturing system 1720, or various components thereof, may be supported by or may refer to at least a portion of at least one processor, where such at least one processor may include one or more processing elements (e.g., a controller, a microprocessor, a microcontroller, a digital signal processor, a state machine, discrete gate logic, discrete transistor logic, discrete hardware components, or any combination of one or more of such elements). In some examples, the described functionality of the manufacturing system 1720, or various components thereof, may be implemented at least in part by instructions (e.g., stored in memory, non-transitory computer-readable medium) executable by such at least one processor.

FIG. 18 shows a flowchart illustrating a method 1800 that supports a bonding structure and related fabrication for a memory system in accordance with examples as disclosed herein. The operations of method 1800 may be implemented by a memory system or its components as described herein. For example, the operations of method 1800 may be performed by a memory system as described with reference to FIGS. 1 through 17. In some examples, a memory system may execute a set of instructions to control the functional elements of the device to perform the described functions. Additionally, or alternatively, the memory system may perform aspects of the described functions using special-purpose hardware.

At 1805, the method may include forming a first layer that includes a polysilicon material. In some examples, aspects of the operations of 1805 may be performed by a poly deposition component 1725 as described with reference to FIG. 17.

At 1810, the method may include forming, above the first layer, a second layer that includes an oxide material. In some examples, aspects of the operations of 1810 may be performed by an oxide deposition component 1730 as described with reference to FIG. 17.

At 1815, the method may include forming, above the second layer, a third layer that includes the polysilicon material. In some examples, aspects of the operations of 1815 may be performed by a poly deposition component 1725 as described with reference to FIG. 17.

At 1820, the method may include removing a first portion of the first layer, a first portion of the second layer, and a third portion of the third layer to form a first cavity. In some examples, aspects of the operations of 1820 may be performed by an etching component 1735 as described with reference to FIG. 17.

At 1825, the method may include forming the oxide material in the first cavity. In some examples, aspects of the operations of 1825 may be performed by an oxide deposition component 1730 as described with reference to FIG. 17.

At 1830, the method may include forming a plurality of second cavities based at least in part on removing at least some of the oxide material formed in the first cavity. In some examples, aspects of the operations of 1830 may be performed by an etching component 1735 as described with reference to FIG. 17.

At 1835, the method may include forming a plurality of first pillars based at least in part on forming a metal material in two or more cavities of the plurality of second cavities. In some examples, aspects of the operations of 1835 may be performed by a metal deposition component 1740 as described with reference to FIG. 17.

In some examples, an apparatus as described herein may perform a method or methods, such as the method 1800. The apparatus may include features, circuitry, logic, means, or instructions (e.g., a non-transitory computer-readable medium storing instructions executable by a processor), or any combination thereof for performing the following aspects of the present disclosure:

Aspect 1: A method, apparatus, or non-transitory computer-readable medium including operations, features, circuitry, logic, means, or instructions, or any combination thereof for forming a first layer that includes a polysilicon material; forming, above the first layer, a second layer that includes an oxide material; forming, above the second layer, a third layer that includes the polysilicon material; removing a first portion of the first layer, a first portion of the second layer, and a third portion of the third layer to form a first cavity; forming the oxide material in the first cavity; forming a plurality of second cavities based at least in part on removing at least some of the oxide material formed in the first cavity; and forming a plurality of first pillars based at least in part on forming a metal material in two or more cavities of the plurality of second cavities.

Aspect 2: The method, apparatus, or non-transitory computer-readable medium of aspect 1, where removing the first portion of the first layer, the first portion of the second layer, and the first portion of the third layer includes operations, features, circuitry, logic, means, or instructions, or any combination thereof for forming a plurality of second pillars that each include a respective second portion of the first layer, a respective second portion of the second layer, and a respective second portion of the third layer that remain after removing the first portion of the first layer, the first portion of the second layer, and the first portion of the third layer.

Aspect 3: The method, apparatus, or non-transitory computer-readable medium of aspect 2, where one or more first pillars within the plurality of first pillars are each positioned between a respective set of at least two second pillars of the plurality of second pillars.

Aspect 4: The method, apparatus, or non-transitory computer-readable medium of any of aspects 1 through 3, further including operations, features, circuitry, logic, means, or instructions, or any combination thereof for forming silicon material in a second cavity of the plurality of second cavities to form a third pillar.

Aspect 5: The method, apparatus, or non-transitory computer-readable medium of any of aspects 1 through 4, further including operations, features, circuitry, logic, means, or instructions, or any combination thereof for forming, prior to forming the first layer, a fourth layer that includes silicon material and is below the first layer.

Aspect 6: The method, apparatus, or non-transitory computer-readable medium of aspect 5, where a first distance between the fourth layer and a top surface of the third layer is less than a second distance between the first layer and a top surface of the oxide material formed in the first cavity.

Aspect 7: The method, apparatus, or non-transitory computer-readable medium of aspect 6, further including operations, features, circuitry, logic, means, or instructions, or any combination thereof for forming, prior to forming the metal material in the plurality of first pillars, aluminum oxide material in the plurality of second cavities to form a plurality of fourth pillars.

Aspect 8: The method, apparatus, or non-transitory computer-readable medium of aspect 7, where a top surface of the aluminum oxide material is flush with the top surface of the third layer or the top surface of the oxide material formed in the first cavity.

Aspect 9: The method, apparatus, or non-transitory computer-readable medium of any of aspects 1 through 8, further including operations, features, circuitry, logic, means, or instructions, or any combination thereof for forming, prior to forming the first layer, a fifth layer that includes the metal material and is below the first layer.

Aspect 10: The method, apparatus, or non-transitory computer-readable medium of any of aspects 1 through 9, further including operations, features, circuitry, logic, means, or instructions, or any combination thereof for forming, prior to forming the first layer, a sixth layer that includes the oxide material and is below the first layer.

Aspect 11: The method, apparatus, or non-transitory computer-readable medium of any of aspects 1 through 10, where a first depth associated with the first layer is greater than a second depth associated with the second layer.

Aspect 12: The method, apparatus, or non-transitory computer-readable medium of any of aspects 1 through 11, where a first depth associated with the first layer is greater than a third depth associated with the third layer.

FIG. 19 shows a flowchart illustrating a method 1900 that supports a bonding structure and related fabrication for a memory system in accordance with examples as disclosed herein. The operations of method 1900 may be implemented by a memory system or its components as described herein. For example, the operations of method 1900 may be performed by a memory system as described with reference to FIGS. 1 through 17.

In some examples, a memory system may execute a set of instructions to control the functional elements of the device to perform the described functions. Additionally, or alternatively, the memory system may perform aspects of the described functions using special-purpose hardware.

At 1905, the method may include forming a first layer that includes a polysilicon material. In some examples, aspects of the operations of 1905 may be performed by a poly deposition component 1725 as described with reference to FIG. 17.

At 1910, the method may include forming, above the first layer, a second layer that includes an oxide material. In some examples, aspects of the operations of 1910 may be performed by an oxide deposition component 1730 as described with reference to FIG. 17.

At 1915, the method may include forming, above the second layer, a third layer that includes the polysilicon material. In some examples, aspects of the operations of 1915 may be performed by a poly deposition component 1725 as described with reference to FIG. 17.

At 1920, the method may include removing a first portion of the first layer, a first portion of the second layer, and a third portion of the third layer to form a first cavity. In some examples, aspects of the operations of 1920 may be performed by an etching component 1735 as described with reference to FIG. 17.

In some examples, removing the first portion of the first layer, the first portion of the second layer, and the third portion of the third layer may include, at 1925, the forming a plurality of second pillars that each include a respective second portion of the first layer, a respective second portion of the second layer, and a respective second portion of the third layer that remain after removing the first portion of the first layer, the first portion of the second layer, and the first portion of the third layer. In some examples, aspects of the operations of 1925 may be performed by an etching component 1735 as described with reference to FIG. 17.

At 1930, the method may include forming the oxide material in the first cavity. In some examples, aspects of the operations of 1930 may be performed by an oxide deposition component 1730 as described with reference to FIG. 17.

At 1935, the method may include forming a plurality of second cavities based at least in part on removing at least some of the oxide material formed in the first cavity. In some examples, aspects of the operations of 1935 may be performed by an etching component 1735 as described with reference to FIG. 17.

At 1940, the method may include forming a plurality of first pillars based at least in part on forming a metal material in two or more cavities of the plurality of second cavities. In some examples, aspects of the operations of 1940 may be performed by a metal deposition component 1740 as described with reference to FIG. 17.

It should be noted that the described methods include possible implementations, and that the operations and the steps may be rearranged or otherwise modified and that other implementations are possible. Further, portions from two or more of the methods may be combined.

An apparatus (e.g., memory system) is described. The following provides an overview of aspects of the apparatus as described herein:

Aspect 13: An apparatus, including: a die including a first region allocated for one or more periphery components associated with a memory array and a second region allocated for the memory array, the first region including: a stack of layers including a first subset of layers and a second subset of layers, where a distance between the first subset of layers and a first surface of the die is smaller than a vertical distance between the second subset of layers and the first surface of the die; and a first plurality of conductive pillars extending through the stack of layers in a direction perpendicular to the first surface of the die, where each conductive pillar of the first plurality of conductive pillars is coupled with a respective contact pad included in the first surface of the die and with the one or more periphery components associated with the memory array, and where each conductive pillar of the first plurality of conductive pillars includes a first portion that extends through the first subset of layers and a second portion that extends through the second subset of layers, where a cross-sectional area of the first portion is greater than a cross-sectional area of the second portion.

Aspect 14: The apparatus of aspect 13, further including: a plurality of pillars extending through the first subset of layers.

Aspect 15: The apparatus of aspect 14, where each pillar within the plurality of pillars includes polysilicon, oxide, or both.

Aspect 16: The apparatus of any of aspects 14 through 15, where one or more pillars of the plurality of pillars are each positioned between two respective conductive pillars of the first plurality of conductive pillars.

Aspect 17: The apparatus of any of aspects 13 through 16, further including: a second plurality of conductive pillars extending through the stack of layers in the direction perpendicular to the first surface of the die, where each conductive pillar of the second plurality of conductive pillars includes a first portion that extends through the first subset of layers and a second portion that extends through the second subset of layers, and where a cross-sectional area of the first portion is greater than a cross-sectional area of the second portion.

Aspect 18: The apparatus of aspect 17, where each pillar within the second plurality of conductive pillars includes metal, silicon, or both.

Aspect 19: The apparatus of any of aspects 13 through 18, where each pillar within the first plurality of conductive pillars includes metal.

Aspect 20: The apparatus of any of aspects 13 through 19, where the one or more periphery components include access line drivers coupled with the memory array, sense components coupled with the memory array, or any combination thereof.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit based on the operation of the device that includes the connected components. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to a condition of moving from an open-circuit relationship between components in which signals are not presently capable of being communicated between the components over a conductive path to a closed-circuit relationship between components in which signals are capable of being communicated between components over the conductive path. If a component, such as a controller, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other if the switch is open. If a controller isolates two components, the controller affects a change that prevents signals from flowing between the components using a conductive path that previously permitted signals to flow.

The term “layer” or “level” used herein refers to a stratum or sheet of a geometrical structure (e.g., relative to a substrate). Each layer or level may have three dimensions (e.g., height, width, and depth) and may cover at least a portion of a surface. For example, a layer or level may be a three dimensional structure where two dimensions are greater than a third, e.g., a thin-film. Layers or levels may include different elements, components, or materials, or combinations thereof. In some examples, one layer or level may be composed of two or more sublayers or sublevels.

The terms “if,” “when,” “based on,” or “based at least in part on” may be used interchangeably. In some examples, if the terms “if,” “when,” “based on,” or “based at least in part on” are used to describe a conditional action, a conditional process, or connection between portions of a process, the terms may be interchangeable.

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorus, boron, or arsenic. Doping may be performed during the initial formation or growth of the substrate, by ion-implantation, or by any other doping means.

A switching component or a transistor discussed herein may represent a field-effect transistor (FET) and comprise a three terminal device including a source, drain, and gate. The terminals may be connected to other electronic elements through conductive materials, e.g., metals. The source and drain may be conductive and may comprise a heavily-doped, e.g., degenerate, semiconductor region. The source and drain may be separated by a lightly-doped semiconductor region or channel. If the channel is n-type (i.e., majority carriers are electrons), then the FET may be referred to as an n-type FET. If the channel is p-type (i.e., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” if a voltage greater than or equal to the transistor's threshold voltage is applied to the transistor gate. The transistor may be “off” or “deactivated” if a voltage less than the transistor's threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a hyphen and a second label that distinguishes among the similar components. If just the first reference label is used in the specification, the description is applicable to any one of the similar components having the same first reference label irrespective of the second reference label.

The functions described herein may be implemented in hardware, software executed by a processing system (e.g., one or more processors, one or more controllers, control circuitry processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or one or more processors.

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. An apparatus, comprising:
a die comprising a first region allocated for one or more periphery components associated with a memory array and a second region allocated for the memory array, the first region comprising:
a stack of layers comprising a first subset of layers and a second subset of layers, wherein a distance between the first subset of layers and a first surface of the die is smaller than a vertical distance between the second subset of layers and the first surface of the die; and
a first plurality of conductive pillars extending through the stack of layers in a direction perpendicular to the first surface of the die, wherein each conductive pillar of the first plurality of conductive pillars is coupled with a respective contact pad included in the first surface of the die and with the one or more periphery components associated with the memory array, and wherein each conductive pillar of the first plurality of conductive pillars comprises a first portion that extends through the first subset of layers and a second portion that extends through the second subset of layers, wherein a cross-sectional area of the first portion is greater than a cross-sectional area of the second portion.

2. The apparatus of claim 1, further comprising:
a plurality of pillars extending through the first subset of layers.

3. The apparatus of claim 2, wherein each pillar within the plurality of pillars comprises polysilicon, oxide, or both.

4. The apparatus of claim 2, wherein one or more pillars of the plurality of pillars are each positioned between two respective conductive pillars of the first plurality of conductive pillars.

5. The apparatus of claim 1, further comprising:
a second plurality of conductive pillars extending through the stack of layers in the direction perpendicular to the first surface of the die, wherein each conductive pillar of the second plurality of conductive pillars comprises a first portion that extends through the first subset of layers and a second portion that extends through the second subset of layers, and wherein a cross-sectional area of the first portion is greater than a cross-sectional area of the second portion.

6. The apparatus of claim 5, wherein each pillar within the second plurality of conductive pillars comprises metal, silicon, or both.

7. The apparatus of claim 1, wherein each pillar within the first plurality of conductive pillars comprises metal.

8. The apparatus of claim 1, wherein the one or more periphery components include access line drivers coupled with the memory array, sense components coupled with the memory array, or any combination thereof.

9. A method, comprising:
forming a first layer that comprises a polysilicon material;
forming, above the first layer, a second layer that comprises an oxide material;
forming, above the second layer, a third layer that comprises the polysilicon material;
removing a first portion of the first layer, a first portion of the second layer, and a third portion of the third layer to form a first cavity;
forming the oxide material in the first cavity;
forming a plurality of second cavities based at least in part on removing at least some of the oxide material formed in the first cavity; and
forming a plurality of first pillars based at least in part on forming a metal material in two or more cavities of the plurality of second cavities.

10. The method of claim 9, wherein removing the first portion of the first layer, the first portion of the second layer, and the first portion of the third layer comprises:
forming a plurality of second pillars that each comprise a respective second portion of the first layer, a respective second portion of the second layer, and a respective second portion of the third layer that remain after removing the first portion of the first layer, the first portion of the second layer, and the first portion of the third layer.

11. The method of claim 10, wherein one or more first pillars within the plurality of first pillars are each positioned between a respective set of at least two second pillars of the plurality of second pillars.

12. The method of claim 9, further comprising:
forming silicon material in a second cavity of the plurality of second cavities to form a third pillar.

13. The method of claim 9, further comprising:
forming, prior to forming the first layer, a fourth layer that comprises silicon material and is below the first layer.

14. The method of claim 13, wherein a first distance between the fourth layer and a top surface of the third layer is less than a second distance between the first layer and a top surface of the oxide material formed in the first cavity.

15. The method of claim 14, further comprising:
forming, prior to forming the metal material in the plurality of first pillars, aluminum oxide material in the plurality of second cavities to form a plurality of fourth pillars.

16. The method of claim 15, wherein a top surface of the aluminum oxide material is flush with the top surface of the third layer or the top surface of the oxide material formed in the first cavity.

17. The method of claim 9, further comprising:
forming, prior to forming the first layer, a fifth layer that comprises the metal material and is below the first layer.

18. The method of claim 9, further comprising:
forming, prior to forming the first layer, a sixth layer that comprises the oxide material and is below the first layer.

19. The method of claim 9, wherein a first depth associated with the first layer is greater than a second depth associated with the second layer.

20. The method of claim 9, wherein a first depth associated with the first layer is greater than a third depth associated with the third layer.
